(19) United States
(12) Patent Application Publication
(10) Pub. No.: US 2003/0141919 A1
(43) Pub. Date: Jul. 31, 2003

(54) Active peaking using differential pairs of transistors

(76) Inventors: Shoujun Wang, Nepean (CA); Tad Kwasniewski, Ottawa (CA); Bill Bereza, Nepean (CA)

Correspondence Address: Shapiro Cohen, Station D, P.O. Box 3440, Ottawa, ON, K1P 6P1, CA

(21) Appl. No.: 10/059,323

(22) Filed: Jan. 31, 2002

(51) Int. Cl. H03K 17/16

(52) U.S. Cl. 327/390

(57) ABSTRACT

A circuit and methods for use in increasing both bandwidth and switching speed of CML circuits. Two differential pairs are provided with one differential pair having a size that is a fraction of the other pair. Thus, one pair will have a size of W while the other will have a size of W/A. Each one of the first differential pair is coupled to at least one of the second pair. By reconfiguring the connections between the two pairs, circuits which have fast charging/discharging times and increased bandwidth are obtained.

### FIELD OF INVENTION

The present invention relates to high speed mixed signal circuits and, more specifically, to devices and methods for faster switching differential current mode logic (CML) circuit.

### BACKGROUND TO THE INVENTION

The ever-increasing speed of new communications devices and new technologies have placed increased pressures on circuit designers. The call for faster network components has highlighted the need for faster switching circuits. Current techniques for “broadbanding” or increasing the bandwidth and speed focus on boosting the gain-bandwidth product or speeding up the changing/switching process. Most of these broadbanding techniques take advantage of some kind of feedback or selective impedance mismatching using inductors or capacitors. These techniques traditionally fall into two categories—inductive peaking or capacitive peaking.

Inductive peaking using spiral inductors is a pioneer proven power efficient technique for bandwidth extension. Adding a spiral inductor in series with the resistive load of CML circuits can partially overcome the parasitic capacitance effects at high frequencies. This results in a fast transient response for the circuit. While such a passive inductor load does not sacrifice low-frequency gain, the self-resonance frequency of the spiral inductor often limits the upper frequency performance. In addition, such a technique suffers from the drawback that spiral inductors require large die areas when implemented. Because of this, spiral inductors can been seen as unsuitable for SOC (system on a chip) implementations. Conversely, active inductors use transistors as an active means of providing inductance in integrated circuits. However, the use of such active inductors leads to an augmented supply voltage and increased nosie.

Capacitance peaking utilizes capacitors placed in strategic locations in the circuit to achieve bandwidth and speed improvements. The capacitance peaking technique is also known in the field as “bootstrapping”. The basic idea of bootstrapping is to create a current using a bootstrap capacitor to charge/discharge the input capacitance. This leads to a reduction of the effective input capacitance, thereby enabling the overall bandwidth to be increased. The bootstrapping technique is effective when driving a large capacitance load. However, capacitors used for bootstrapping usually require a large percentage (15-35%) of the total circuit area.

Based on the above, a new technique for achieving increased bandwidth and speed is needed. Such a technique should take advantage of current CMOS technology and avoid the large die-area requirements of the previous techniques.

### SUMMARY OF THE INVENTION

The present invention provides a circuit and methods for use in increasing both bandwidth and switching speed of CML circuits. Two differential pairs are provided with one differential pair having a size that is a fraction of the other pair. Thus, one pair will have a size of W while the other will have a size of W/A. Each one of the first differential pair is coupled to at least one of the second pair. By reconfiguring the connections between the two pairs, circuits which have fast charging/discharging times and increased bandwidth are obtained.

In a first aspect of the present invention a circuit includes:

a first differential pair of transistors,

a second differential pair of transistors wherein:

each one of the first differential pair is coupled to at least one of the second differential pair,

a first size (W₁) of a first one of the first differential pair matches a size of the second one of the first differential pair,

a second size (W₂) of a first one of the second differential pair matches a size of the second one of the second differential pair,

the first size is a multiple of the second size such that

$$W1 = \frac{W2}{A}$$

where A≧1.

In a second aspect of the present invention, a D-type flip-flop circuit includes:

a first differential pair of transistors,

a second differential pair of transistors

wherein:

each one of the first differential pair is coupled to at least one of the second differential pair,

a first size (W₁) of a first one of the first differential pair matches a size of the second one of the first differential pair,

a second size (W₂) of a first one of the second differential pair matches a size of the second one of the second differential pair,

the first size is a multiple of the second size such that

$$W1 = \frac{W2}{A}$$

where A≧1.

In a third aspect of the present invention, a driver circuit for low voltage differential signalling, the circuit includes:

a first differential pair of transistors,

a second differential pair of transistors

wherein:

each one of the first differential pair is coupled to at least one of the second differential pair,

a first size (W₁) of a first one of the first differential pair matches a size of the second one of the first differential pair,

a second size (W₂) of a first one of the second differential pair matches a size of the second one of the second differential pair,

the first size is a multiple of the second size such that

$$W1 = \frac{W2}{A}$$

where A≧1.

### BRIEF DESCRIPTION OF THE DRAWINGS

A better understanding of the invention may be obtained by reading the detailed description of the invention below, in conjunction with the following drawings, in which:

FIG. 1 is a circuit diagram of a differential pair according to the prior art;

FIG. 2 is a circuit diagram of a split differential pair;

FIG. 3 is a circuit diagram of a parallel embodiment of the invention;

FIG. 4 is a circuit diagram of a simplified equivalent circuit to the parallel embodiment illustrated in FIG. 3;

FIG. 5 is a circuit diagram similar to FIG. 4 showing static voltages under logic LOW conditions;

FIG. 6 is a circuit diagram similar to FIG. 4 showing static voltages under logic HIGH conditions;

FIG. 7 is a circuit diagram of a series embodiment of the invention;

FIG. 8 is a circuit diagram of a simplified equivalent circuit to the series embodiment in FIG. 7;

FIG. 9 is a circuit diagram similar to FIG. 8 showing the static voltages under logic LOW conditions;

FIG. 10 is a circuit diagram similar to FIG. 8 showing the static voltages under logic HIGH conditions;

FIG. 11 is a circuit incorporating the parallel embodiment with an inductive load;

FIG. 12 is a circuit for a D-type flip-flop incorporating the parallel embodiment;

FIG. 13 is a circuit for an LVDS driver using two instances of the parallel embodiment; and

FIG. 14 is another LVDS driver circuit using two instances of the series embodiment.

### DETAILED DESCRIPTION

The present invention involves a technique that has been termed active peaking. This non-inductive transient peaking technique, at its essence, splits one differential pair of transistors into two differential pairs with different sizes. These two differential pairs are then reconfigured such that common source voltages are dynamically exchanged before and after the switching transition. Contrary to the ordinary design practice of keeping the common-source voltage as constant as possible, active peaking essential takes advantage of the dynamic movement of the common-source voltage to achieve peaking. During switching transients, the dynamic charge redistribution between the charge capacitances of two differential pairs result in a peaking current which speeds up the charge-discharge process.

The well known Darlington pair and cascode are two good examples of composite devices that achieve better performance that is not achievable by individual transistors. Active peaking achieves a similar better performance by splitting a large differential pair into two differential pairs—one with a large size and another with a smaller size related to the size of the larger pair. As contrasted with the single-ended Darlington pair and cascode, the new composite device is differential and its working principle relies on differential operation as well. With different configurations of the gate/source/drain connections, numerous useful composite devices have been constructed. Each new composite device has some distinct new feature. For these devices, a peaking phenomena similar to inductive or capacitance peaking has been noticed. Since no peaking inductor or capacitor is used and only active devices are involved, the principle has been named “active peaking”.

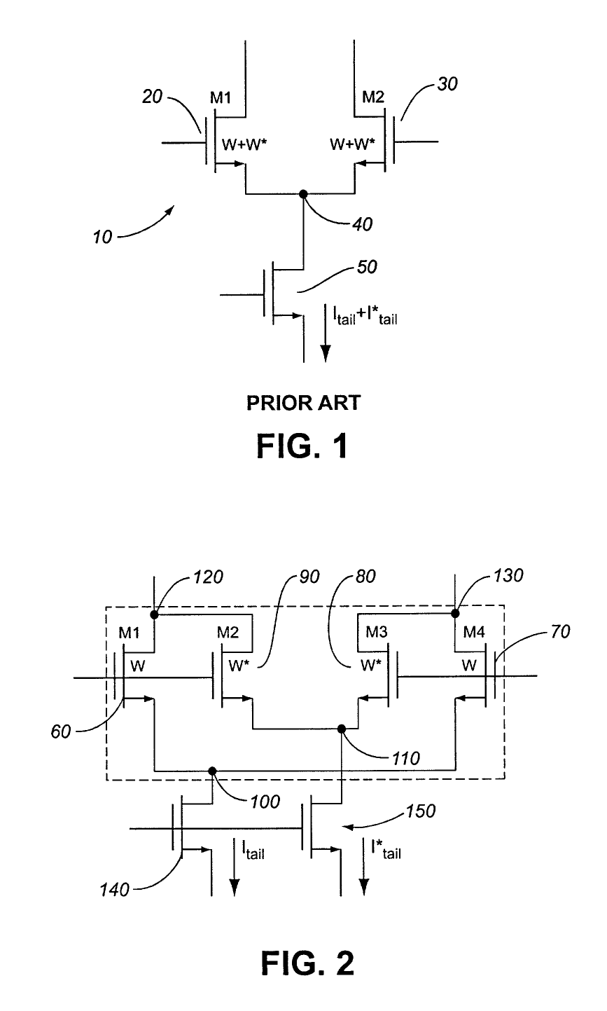

Referring to FIG. 1, a circuit diagram of a differential pair according to the prior art is illustrated. The differential pair 10 is comprised of two transistors 20, 30 each with a size W+W*. The source leads of these transistors 20, 30 are coupled at a common point 40 and the tail current of this arrangement is provided through a third transistor 50. This tail current has a value of Iₜₐᵢₗ+I*ₜₐᵢₗ.

Referring to FIG. 2, a circuit diagram is presented of an arrangement that illustrates how splitting a differential pair and reconfiguring the connections can lead to different results. Two differential pairs are illustrated with the first differential pair consisting of transistors 60, 70 and the second differential pair consisting of transistors 80, 90. The transistors 60, 70 of the first differential pair each have a size W while each transistor 80, 90 of the second differential pair has a size W*. As can be seen, the source leads of the transistors of the first differential pair are coupled at a point 100. Similarly, the source leads of the transistors of the second differential are coupled at a point 110. However, the two pairs are coupled to each other as a drain lead of one transistor of the first pair is coupled to a drain lead of one of the second pair. Thus, transistors 60, 90 have their drain leads coupled to a common point 120 while transistors 70, 80 have their drain leads coupled to a common point 130. Equally, the transistors with coupled drain leads have a common gate connection and transistors 70, 80 sharing their common gate connection. The result of this configuration is that, instead of one tail current having a value of Iₜₐᵢₗ+I*ₜₐᵢₗ, two tail currents of value Iₜₐᵢₗ and I*ₜₐᵢₗ are generated and passed through tail transistors 140, 150. Tail transistors 140, 150 share a common gate lead while the drain of tail transistor 140 is connected to common point 100 and the drain of tail transistor 150 is connected to common point 110.

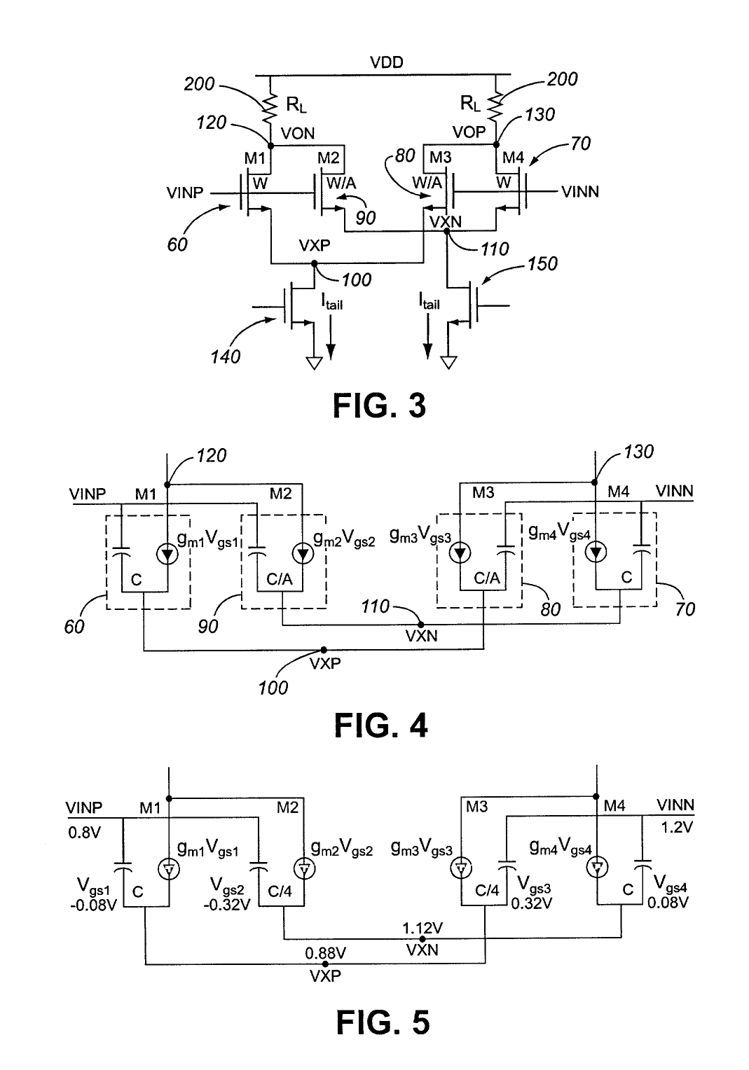

Referring to FIG. 3, a circuit diagram of a parallel embodiment according to the invention is illustrated. For ease of reference, reference numbers similar to those in FIG. 2 have been used. Node voltage VXP is measured at common node 100 while node voltage VXN is measured at common node 110. Similarly, node voltage VON is measured at node 120 and node voltage VOP is measured at node 130. Load resistances R_{L} are connected between node 120 and power rail V_{DD} and between node 130 and V_{DD}. Gate voltages VINP is applied at the common gate connection shared by transistors 60, 90 and gate voltage VINN is applied to the common gate connection shared by transistors 70, 80. The interesting point about the circuit in FIG. 3 is that the transistor sizes are related—the first differential pair (transistors 60, 70) has a size W while the second differential pair (transistors 80, 90) has a size W/A, a fraction of the size of the first differential pair. Also, the tail current Iₜₐᵢₗ is produced across both tail transistors 140, 150.

It should also be noted that in FIG. 3 each one of the first differential pair of transistors 60, 70 share a common gate connection with one of the second differential pair of transistors 80, 90. The transistor 90 shares a gate connection with transistor 60 and this gate connection is provided with input voltage VINP. Transistor 70 shares a gate connection with transistor 80 and this gate connection is provided with the other input voltage VINN. In contrast to the connections in FIG. 2, the source connections of transistor 60 of the first pair and of transistor 80 of the second pair are connected at common node 100. This common node 100 is also connected the drain connection of tail transistor 140. Similarly, source connections for transistor 90 and transistor 70 are connected to the drain connection of tail transistor 150 by way of common node 110. As can be seen, transistor 60 and transistor 90 share a common drain connection at common node 120 where voltage VON is measured. Similarly, transistor 80 and transistor 70 share a drain connection at common node 130 where voltage VOP is measured.

Referring to FIG. 4, a simplified equivalent circuit equivalent to the circuit in FIG. 3 is illustrated. The equivalent circuit assumes an ideal current source and the transistors are modelled as voltage controlled current sources with a gate capacitance of C or C/A. If the transistor has a size of W, then the equivalent has a capacitance of C while a transistor size of W/A has an equivalence with capacitance of C/A.

Under static conditions (logic LOW or HIGH), the gate capacitances of the pairs comprise a static-voltage divider between the differential inputs VINP and VINN respectively. The common source voltages VXP and VXN can then be derived as

$$VXP = \frac{A}{1 + A} ( VINP - VINN ) + VINN$$

$$VXN = \frac{1}{1 + A} ( VINP - VINN ) + VINN$$

Before and after the switching transition, the node voltages VXP and VXN are exchanged from one node to the other. During switching transients, dynamic charge redistribution occurs between the gate capacitances of transistors 60 and 80 and transistors 90 and 70 respectively. The redistributed charge is injected into the channel through the gate, resulting in a transient current surge. This accelerates the charging/discharging process.

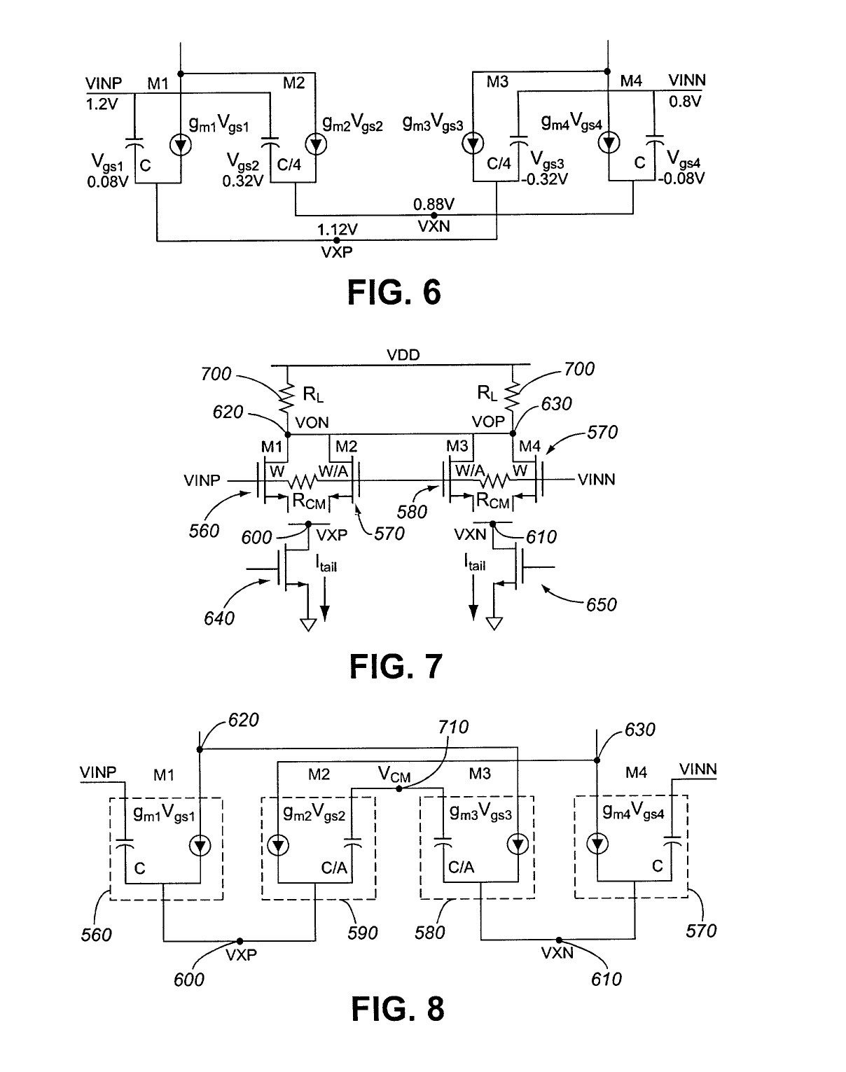

For further clarification, an example using FIGS. 5 and 6 is provided. FIGS. 5 and 6 are copies of the circuit of FIG. 4 but under different conditions. FIG. 6 shows the static voltages under logic HIGH conditions and FIG. 5 shows the static voltage under logic LOW conditions. The voltages illustrated and discussed are calculated using the simplified equivalent circuit model of FIG. 4. For the example, the following values are used: A=4, HIGH=1.2, LOW=0.8V. Assuming VINP is switching from LOW to HIGH, because VXP is lowered (and VXN is raised), there is a large gate overdrive voltage V_{gs1}=VINP−VXP=0.32V. Similarly, there is a small gate overdrive voltage V_{gs2}=VINP−VXN=+0.08V. These result in a large channel charging current in one arm with V_{gs1}=0.32V in the end and in a small channel charging current in the other arm with V_{gs2}=0.08V. At the end of the switching process, VXP is raised to the previous value of VXN(1.12V) and VXN is lowered to the previous value of VXP(0.88V). Consequently, a current/voltage peaking is observed during the switching transient. A similar peaking phenomenon is observed when VINP is switching from HIGH to LOW. The dynamic charge redistribution between the gate capacitances of transistors 60 and 80 and transistors 90 and 70 are responsible for the common source voltage shifting and the observed transient peaking.

A second embodiment of the invention also utilizes two differential pairs with scaled transistor sizes. However, this second embodiment utilizes different connections between the two differential pairs. Referring to FIG. 7, a series connected embodiment of the invention is illustrated. The two differential pairs, composed of transistors 560, 570 and transistors 580, 590 have differing sizes. The transistors 560, 570 each have a transistor size of W while the transistors 580, 590 each have a transistor size of W/A. The source leads of transistors 560, 590 are coupled together at node 600, and the source leads of transistors 580 and 570 are connected at node 610. Also, the drain leads of transistors 560 and 580 are connected at node 620 while the drain leads of transistors 590 and 570 are connected at node 630. The gate leads of transistors 580, 590 is connected to a virtual ground—the common node voltage Vcm sensed by two resistors R_{cm}. The gate of transistor 560 is fed voltage VINP and the gate of transistor 570 is fed voltage VINN.

Load resistances 700 are coupled between nodes 620, 630 and power rail V_{DD}. Tail transistor 640 has a drain connected to node 600 and has tail current Iₜₐᵢₗ. Similarly, tail transistor 650 has its drain connected to node 610 and also has tail current Iₜₐᵢₗ.

Using the same model and assumptions as used in FIG. 4, FIG. 8 is a simplified equivalent circuit to FIG. 7. Under static conditions (logic HIGH or LOW), the gate capacitances of transistors 560 and 590 and transistors 580 and 570, comprise a static voltage divider between VINP and V_{cm} and V_{cm} and VINN, respectively. Node 710 with voltage V_{cm}, is the common virtual ground to which the gates of transistors 580, 590 are connected. The common source node voltages VXP and VXN (at nodes 600 and 610 respectively) can be derived as

$$VXP = \frac{A}{1 + A} ( VINP - {V}_{c m} ) + {V}_{c m}$$

$$VXN = \frac{A}{1 + A} ( VINP - {V}_{c m} ) + {V}_{c m}$$

Similar to the previous embodiment, before and after the switching transition, the node voltages VXP and VXN are exchanged from one node to the other. During switching transients, dynamic charge redistribution occurs between the gate capacitances of transistors 560 and 590 and transistors 580 and 570 respectively. The redistributed charge is injected into the channel through the gate, resulting in a transient current surge. This accelerates the charging/discharging process.

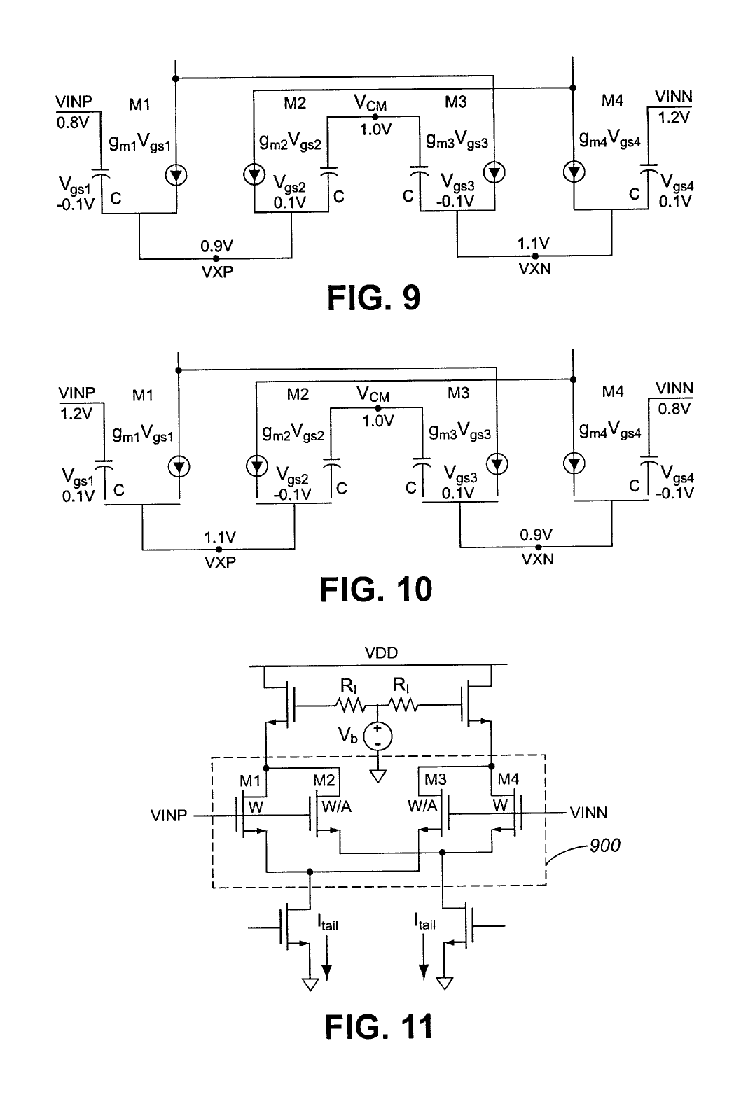

To further illustrate the embodiment, an example using FIGS. 9 and 10 is provided. FIG. 9 provides the voltages at the different nodes under static conditions of logic LOW while FIG. 10 provides the voltages at the different nodes under static conditions of logic HIGH. For the example and for FIGS. 9 and 10 the following values are used: A=1, HIGH=1.2V, LOW=0.8V. Assuming VINP is switched from LOW to HIGH, because VXP is lowered, there is a large gate overdrive voltage V_{gs1}=VlNP−VXP=0.3V. This results in a large channel charging current and at the end V_{gs1}=0.1V. VXP is thus raised to VXN. Consequently, a current/voltage peaking is observed during the switching transient. A similar peaking phenomenon is observed when VINP is switched from HIGH to LOW. The dynamic charge redistribution between the gate capacitances of transistors 560 and 590 and transistors 580 and 570 is responsible for the common source voltage shifting and the observed transient peaking.

From the above, the underlying principle of active peaking relies on the large signal and differential operation of the differential pair. Also, active peaking is input-switched triggered, a major difference from active inductors.

It should be noted that the embodiment of the invention illustrated in FIGS. 3-6 is referred to as the parallel embodiment, while the embodiment illustrated in FIGS. 7-10 is referred to as the series embodiment.

The concepts illustrated above rely on transistor biasing and sizing. For best results, for high speed CML circuits, ideas from the so-called current overdriven concept can be used. The current overdriven concept is to make the tail current (Iₜₐᵢₗ)larger than the maximum conducting current allowed for a given gate width or to make the gate width smaller than the minimum commutating width required for a given tail current. Current overdriven (Iₜₐᵢₗ>I_{d} where I_{d} is the DC conducting current for both differential pair transistors) can be achieved by increasing Iₜₐᵢₗ for a fixed device/transistor size W or by reducing W for a fixed tail current Iₜₐᵢₗ. Under current overdriven operation, a differential pair works like a class-AB amplifier with neither transistor fully turned off. Since no channel forming is needed, the changing process is fast and the common source voltage is lowered, further speeding up the charging process as the channel conducting current is increased.

For active peaking, from a large-signal transient response viewpoint, increasing Iₜₐᵢₗ and reducing W both increase the slew rate to thereby reduce the rising/falling time. From a small signal frequency response viewpoint, increasing Iₜₐᵢₗ and reducing W both reduce the RC constant and thus increase the bandwidth. Assuming that W_{M1,M4} is the transistor size for the larger of the two differential pairs used in active peaking and assuming that W_{M2,M3} is the transistor for the smaller pair, an active peaking circuit can be designed using the following:

a) For a given tail current Iₜₐᵢₗ, the minimum transistor size Wₘᵢₙ corresponding to current commutating is first determined for the large differential pair—W_{M1,M4}=Wₘᵢₙ.

b) The transistor size for the smaller differential pair is scaled from the minimum transistor size Wₘᵢₙ. This means that W_{M2,M3}=Wₘᵢₙ/A where A>1 for the parallel embodiment and A≧1 for the series embodiment. This choice will make both the differential pairs work under current overdriven conditions.

c) The load resistance R_{L} is calculated from V_{swing}/I_{d} where I_{d} is the DC conducting current calculated for a transistor size of (1+1/A)xWₘᵢₙ and V_{swing} is a given voltage swing. The final R_{L} value involves a trade-off between gain and bandwidth.

As can be seen, the scaling factor A is fairly important—it determines the amount of peaking. A large A results in large peaking. However, there is a trade-off between gain and bandwidth or speed and voltage swing. As the scaling factor increases, the amount of peaking increases and the propagation delay and settling time are shortened. These are all at the expense of voltage swing. The reduced swing can be compensated for by increasing R_{L} at the cost of reduced bandwidth. A decision regarding trade-offs should be made depending on the intended applications and on the desired characteristics of those applications. For high-speed CML circuit design, as a rule of thumb, the scaling factor can be set around A=2-5 for the parallel embodiment and around A=1˜4 for the series embodiment.

The circuits illustrated in the figures can be used in multiple applications. The parallel and series embodiments can be used for, among others, SOC (system on a chip) designs and LVDS (low-voltage differential signalling) drivers with built in pre-emphasis, as well as D-type flip-flops with fast latching operations.

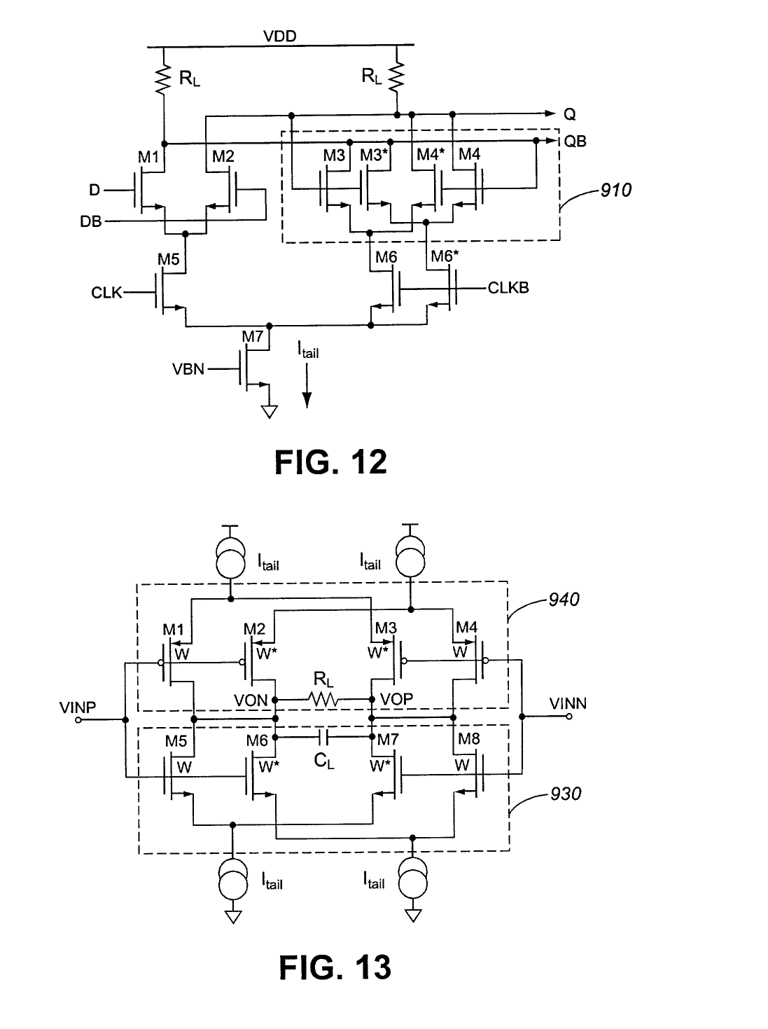

As can be seen in FIG. 11, the parallel embodiment of the invention can be incorporated with an active inductor load. The box 900 outlines the parallel embodiment in the circuit of FIG. 11. However, the series embodiment of the invention can also be used in this circuit.

In FIG. 12, the parallel embodiment (box 910) is incorporated in a circuit for a D-latch. The resulting D-type flip-flop of FIG. 12 features fast latching operation and improved setup and hold times. Again, the series embodiment may be used in this application in place of the parallel embodiment.

FIG. 13 illustrates an LVDS driver circuit with built-in pre-emphasis using two instances of the parallel embodiment. As can be seen, box 940 delineates the first parallel embodiment using pMOS transistors while box 930 delineates the second parallel embodiment using nMOS transistors. R_{L} and C_{L} in FIG. 13 are loads.

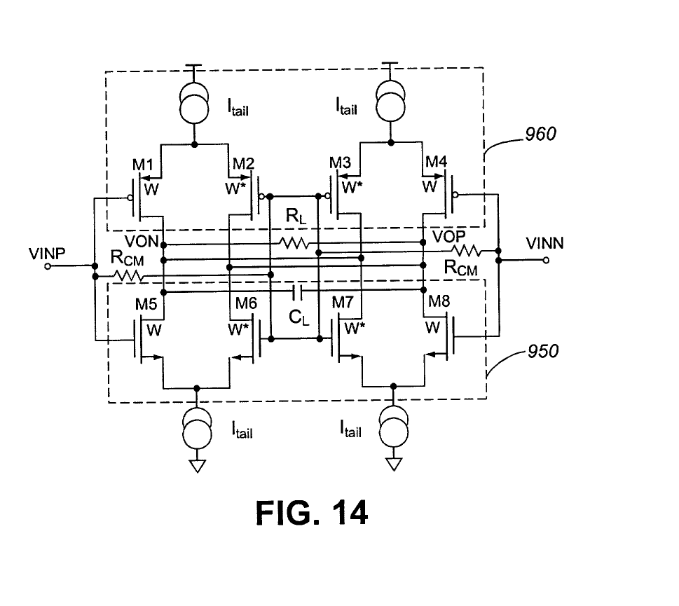

FIG. 14 illustrates another LVDS driver circuit with built-in pre-emphasis. While R_{L} and C_{L} in FIG. 14 are loads, box 960 delineates one series embodiment using pMOS transistors while box 950 delineates another using nMOS transistors.

A person understanding the above-described invention may now conceive of alternative designs, using the principles described herein. All such designs which fall within the scope of the claims appended hereto are considered to be part of the present invention.

I claim:

1. A circuit including:
a first differential pair of transistors,
a second differential pair of transistors wherein:
each one of the first differential pair is coupled to at least one of the second differential pair,
a first size (W₁) of a first one of the first differential pair matches a size of the second one of the first differential pair,
a second size (W₂) of a first one of the second differential pair matches a size of the second one of the second differential pair,
the first size is a multiple of the second size such that
$$W1 = \frac{W2}{A}$$
where A≧1.

2. A circuit as claimed in claim 1 wherein drain connections of the first one of the first pair and of the first one of the second pair are coupled at a first common node, gate connections of the first one of the first pair and of the first one of the second pair are coupled to a first input voltage and source connections of the first one of the first pair and of the second one of the second pair are coupled at a second common node.

3. A circuit as in claim 2 wherein drain connections of the second one of the first pair and of the second one of the second pair are coupled at a third common node, gate connections of the second one of the first pair and of the second one of the second pair are coupled to a second input voltage and source connections of the second one of the first pair and of the first one of the second pair are coupled at a fourth common node.

4. A circuit as in claim 1 wherein drain connections of the first one of the first pair and of the second one of the second pair are coupled at a first common node, a gate connection of the first one of the first pair is coupled to a first input voltage, source connections of the first one of the first pair and of the first one of the second pair are coupled at a second common node, and gate connections of both ones of the second pair are connected to a virtual ground.

5. A circuit as in claim 4 wherein drain connections of the second one of the first pair and of the first one of the second pair are coupled at a third common node, a gate connection of the second one of the first pair is connected to a second input voltage and source connection of the second one of the first pair and of the second one of the second pair are coupled at a fourth common node.

6. A circuit as in claim 2 further including a tail transistor with a drain connection coupled to the second common node.

7. A circuit as in claim 3 further including a tail transistor with a drain connection coupled to-the fourth common node.

8. A circuit as in claim 4 further including a tail transistor with a drain connection coupled to the second common node.

9. A circuit as in claim 5 further including a tail transistor with a drain connection coupled to the fourth common node.

10. A circuit as in claim 3 further including an active inductor load.

11. A D-type flip-flop circuit including:
a first differential pair of transistors,
a second differential pair of transistors
wherein:
each one of the first differential pair is coupled to at least one of the second differential pair,
a first size (W₁) of a first one of the first differential pair matches a size of the second one of the first differential pair,
a second size (W₂) of a first one of the second differential pair matches a size of the second one of the second differential pair,
the first size is a multiple of the second size such that
$$W1 = \frac{W2}{A}$$
where A≧1.

12. A circuit as in claim 11 wherein drain connections of the first one of the first pair and of the first one of the second pair are coupled at a first common node, gate connections of the first one of the first pair and of the first one of the second pair are coupled to a first input voltage and source connections of the first one of the first pair and of the second one of the second pair are coupled at a second common node.

13. A circuit as in claim 12 wherein drain connections of the second one of the first pair and of the second one of the second pair are coupled at a third common node, gate connections of the second one of the first pair and of the second one of the second pair are coupled to a second input voltage and source connections of the second one of the first pair and of the first one of the second pair are coupled at a fourth common node.

14. A driver circuit for low voltage differential signalling, the circuit including:
a first differential pair of transistors, a second differential pair of transistors wherein:
each one of the first differential pair is coupled to at least one of the second differential pair,
a first size (W₁) of a first one of the first differential pair matches a size of the second one of the first differential pair,
a second size (W₂) of a first one of the second differential pair matches a size of the second one of the second differential pair,
the first size is a multiple of the second size such that
$$W1 = \frac{W2}{A}$$
where A≧1.

15. A circuit as in claim 14 wherein drain connections of the first one of the first pair and of the first one of the second pair are coupled at a first common node, gate connections of the first one of the first pair and of the first one of the second pair are coupled to a first input voltage and source connections of the first one of the first pair and of the second one of the second pair are coupled at a second common node.

16. A circuit as in claim 15 wherein drain connections of the second one of the first pair and of the second one of the second pair are coupled at a third common node, gate connections of the second one of the first pair and of the second one of the second pair are coupled to a second input voltage and source connections of the second one of the first pair and of the first one of the second pair are coupled at a fourth common node.

17. A circuit as in claim 14 wherein drain connections of the first one of the first pair and of the second one of the second pair are coupled at a first common node, a gate connection of the first one of the first pair is coupled to a first input voltage, source connections of the first one of the first pair and of the first one of the second pair are coupled at a second common node, and gate connections of both ones of the second pair are connected to a virtual ground.

18. A circuit as in claim 17 wherein drain connections of the second one of the first pair and of the first one of the second pair are coupled at a third common node, a gate connection of the second one of the first pair is connected to a second input voltage and source connection of the second one of the first pair and of the second one of the second pair are coupled at a fourth common node.
